(19) United States
(12) Patent Application Publication
(10) Pub. No.: US 2026/0144004 A1
(43) Pub. Date: May 21, 2026

(54) PROCESSING METHOD OF CHUCK TABLE, MANUFACTURING METHOD OF PROCESSED CHUCK TABLE, PROCESSING METHOD OF WORKPIECE, MANUFACTURING METHOD OF PROCESSED WAFER, AND PROCESSING APPARATUS

(71) Applicant: DISCO CORPORATION, Tokyo (JP)

(72) Inventor: Hiroki ABE, Tokyo (JP)

(21) Appl. No.: 19/350,733

(22) Filed: Oct. 6, 2025

(30) Foreign Application Priority Data
Nov. 19, 2024 (JP) 2024-201628

(51) Int. Cl. H01L 21/683; B24B 7/22; B24B 37/10; B24B 41/06; H01L 21/304

(52) U.S. Cl. CPC H10P 72/70; B24B 7/228; B24B 37/107; B24B 41/06; H10P 52/00

(57) ABSTRACT

Provided is a processing method of a chuck table. The processing method of a chuck table includes processing a holding member forming a holding surface of a chuck table that has the holding surface for holding a workpiece and that is rotatable about a rotational axis transverse to the holding surface. In processing the holding member, the holding member is processed such that the holding surface has an outer peripheral protruding shape in which, relative to an extended surface of a surface formed by a central region which is a portion of the holding surface including a center thereof, at least a part of an outer peripheral region that is on an outer side of the central region is protruding in a direction transverse to the extended surface.

### BACKGROUND OF THE INVENTION

### Field of the Invention

The present invention relates to a processing method of a chuck table that holds a workpiece such as a semiconductor wafer and a manufacturing method of a processed chuck table that uses the processing method. Moreover, the present invention relates to a processing method of a workpiece that uses the processing method of a chuck table and a manufacturing method of a processed wafer that uses the processing method of a workpiece. Further, the present invention relates to a processing apparatus that processes a chuck table.

### Description of the Related Art

Device chips that are mounted on electronic appliances including mobile phones and personal computers are manufactured by processing of semiconductor wafers.

On one side of a plate-shaped semiconductor wafer that is a workpiece, a plurality of planned dividing lines (streets) are set in a grid pattern, and such devices as integrated circuits (ICs) and large-scale integration (LSI) circuits are formed in the rectangular regions partitioned by the planned dividing lines. The semiconductor wafer on which the devices are formed is divided into a plurality of device chips by being cut along each of the planned dividing lines.

In recent years, in manufacturing such device chips, wafers are thinned to make the chips smaller and lighter. A wafer is thinned by, for example, holding the wafer on a chuck table, and rotating the chuck table together with the wafer, while bringing rotating grindstones into contact with the wafer.

Wafers that are to be thinned most commonly have a circular shape but also have shapes other than a circular shape. For example, Japanese Patent Laid-open No. 2015-205358 particularly describes an apparatus and a method used for grinding a rectangular wafer.

When a wafer is to be ground by the grindstones and the wafer being brought into contact with each other while each independently rotating, how easily the wafer can be ground depends on the area of contact between the grindstones and the wafer. In a case where other conditions are the same, in principle, the smaller the area of contact is, the more easily the wafer is ground, while the larger the area of contact is, the less easily the wafer is ground.

Accordingly, depending on the shape of the wafer, minute irregularities attributable to the size of the area of contact are sometimes formed on the face side of the ground wafer. For example, in a case where the wafer has a rectangular shape and is ground by grindstones coming into contact with the wafer while drawing an annular path, when the state in which the path followed by the grindstones passes through corners of the rectangular wafer and the state in which the path of the grindstones passes through the intermediate points of the sides of the rectangular wafer are compared with each other, the area of contact is greater in the former state than in the latter state. Since the size of the area of contact affects how easily the wafer can be ground, the face side of the ground wafer has such a shape that regions along the diagonal lines slightly protrude relative to regions along line segments that connect the intermediate points of the opposite sides.

That is, in a case where the wafer is a polygon, its width (size of a line segment that passes through the center of the polygon and that has both ends at the points of intersection with the sides or corners of the polygon) differs depending on the location, and the abovementioned irregularities are generated due to such difference.

The irregularities on the face side of the wafer can lead to uneven thickness of the wafer. The wafer having an uneven thickness can cause such defects as a variation in thickness of each chip when the wafer is subsequently divided into chips, for example.

One document describing a technology for handling such a problem is Japanese Patent Laid-open No. 2020-55080. According to the grinding method described in Japanese Patent Laid-open No. 2020-55080, a chuck table that holds a rectangular wafer is provided with a holding surface of the same shape as the wafer and the holding surface is ground, so that the same irregularities as those formed on the face side of the wafer when the wafer is subsequently ground are formed on the holding surface of the chuck table. Grinding the wafer in a state in which the wafer is held on the holding surface having irregularities and forming the same irregularities as those of the holding surface on the face side of the wafer can produce a wafer having a uniform thickness.

### SUMMARY OF THE INVENTION

However, even when such grinding is performed, there have been cases where the problem of uneven thickness of the wafer is not necessarily solved to a sufficient extent. One of the causes is the difference in the material between the chuck table and the wafer. Even when grinding is performed by the same grindstones in the same manner, the difference in the material of the grinding targets results in the difference in the easiness of grinding. Accordingly, the shape of irregularities that are formed on the ground surface is different between the case where grinding is performed on the holding surface of the chuck table and the case where grinding is performed on the wafer, causing uneven thickness of the wafer.

Accordingly, an object of the present invention is to provide a new technology that relates to a polygonal workpiece and that can reduce the uneven thickness of the processed workpiece.

In accordance with an aspect of the present invention, there is provided a processing method of a chuck table, including positioning, relative to each other, the chuck table that has a holding surface for holding a workpiece and that is rotatable about a rotational axis transverse to the holding surface and a processing unit that includes a processing member for processing the holding surface of the chuck table, such that at least a part of the processing member overlaps the holding surface, and processing a holding member forming the holding surface of the chuck table. In processing the holding member, the holding member is processed such that the holding surface has an outer peripheral protruding shape in which, relative to an extended surface of a surface formed by a central region that is a portion of the holding surface including a center thereof, at least a part of an outer peripheral region that is on an outer side of the central region is protruding in a direction transverse to the extended surface.

According to the aspect of the present invention, in processing the holding member, preferably, the processing member is rotated along the holding surface such that a rotational diameter in a direction along the holding surface is smaller than a minimum width of the holding surface, while the chuck table is rotated about the rotational axis, and the chuck table and the processing member are moved relative to each other in the direction along the holding surface, while the processing member is brought into contact with the central region of the holding surface, to thereby process a portion that forms the central region of the holding surface in the holding member.

According to the aspect of the present invention, preferably, in processing the holding member, the processing member is rotated along the holding surface such that a rotational diameter in a direction along the holding surface is smaller than a minimum width of the holding surface, while the chuck table is rotated about the rotational axis, the chuck table and the processing member are moved relative to each other in the direction along the holding surface and in a direction transverse to the holding surface, while the processing member is brought into contact with the holding surface, and at least a part of a portion that forms the outer peripheral region of the holding surface in the holding member is thereby processed such that the holding surface formed by the holding member has the outer peripheral protruding shape.

According to the aspect of the present invention, in processing the holding member, preferably, the processing member is rotated along the holding surface such that a rotational diameter in a direction along the holding surface is smaller than a minimum width of the holding surface, while the chuck table is rotated about the rotational axis, the chuck table and the processing member are moved relative to each other in the direction along the holding surface, while the processing member is brought into contact with the holding surface, and at that time, a rotational speed of one of or both the chuck table and the processing member is changed, and at least a part of a portion that forms the outer peripheral region of the holding surface in the holding member is thereby processed such that the holding surface formed by the holding member has the outer peripheral protruding shape.

In accordance with another aspect of the present invention, there is provided a manufacturing method of a processed chuck table for manufacturing a processed chuck table by processing a chuck table, including positioning, relative to each other, the chuck table that has a holding surface for holding a workpiece and that is rotatable about a rotational axis transverse to the holding surface and a processing unit that includes a processing member for processing the holding surface of the chuck table, such that at least a part of the processing member overlaps the holding surface, and processing a holding member that forms the holding surface of the chuck table. In the processing the holding member, the holding member is processed such that the holding surface has an outer peripheral protruding shape in which, relative to an extended surface of a surface formed by a central region that is a portion of the holding surface including a center thereof, at least a part of an outer peripheral region that is on an outer side of the central region is protruding in a direction transverse to the extended surface.

In accordance with a further aspect of the present invention, there is provided a processing method of a workpiece, including positioning, relative to each other, a chuck table that has a holding surface for holding the workpiece and that is rotatable about a rotational axis transverse to the holding surface and a processing unit that includes a processing member for processing the holding surface of the chuck table, such that at least a part of the processing member overlaps the holding surface, processing a holding member that forms the holding surface of the chuck table, holding the workpiece on the holding surface formed by the holding member, after the processing the holding member, and processing the workpiece by moving the chuck table and a grinding wheel to which grindstones are mounted relative to each other along a rotational axis direction while rotating the chuck table about the rotational axis, rotating the grinding wheel, and bringing the rotating grindstones into contact with the workpiece held on the holding surface, after the holding the workpiece on the holding surface. The workpiece is a plate-shaped, polygonal object, and, in processing the holding member, the holding member is processed such that the holding surface has an outer peripheral protruding shape in which, relative to an extended surface of a surface formed by a central region that is a portion of the holding surface including a center thereof, at least a part of an outer peripheral region that is on an outer side of the central region is protruding in a direction transverse to the extended surface.

In accordance with a still further aspect of the present invention, there is provided a manufacturing method of a processed wafer for manufacturing a processed wafer by processing a wafer which is a workpiece, including positioning, relative to each other, a chuck table that has a holding surface for holding the workpiece and that is rotatable about a rotational axis transverse to the holding surface and a processing unit that includes a processing member for processing the holding surface of the chuck table, such that at least a part of the processing member overlaps the holding surface, processing a holding member that forms the holding surface of the chuck table, holding the workpiece on the holding surface formed by the holding member, after the processing the holding member, and processing the workpiece by moving the chuck table and a grinding wheel to which grindstones are mounted relative to each other along a rotational axis direction while rotating the chuck table about the rotational axis, rotating the grinding wheel, and bringing the rotating grindstones into contact with the workpiece held on the holding surface, after the holding the workpiece on the holding surface. The workpiece is a plate-shaped, polygonal wafer, and, in processing the holding member, the holding member is processed such that the holding surface has an outer peripheral protruding shape in which, relative to an extended surface of a surface formed by a central region that is a portion of the holding surface including a center thereof, at least a part of an outer peripheral region that is on an outer side of the central region is protruding in a direction transverse to the extended surface.

In accordance with a still further aspect of the present invention, there is provided a processing apparatus for processing a workpiece, including a chuck table to which a holding member that forms a holding surface for holding the workpiece is attached and that rotates along a rotational axis transverse to the holding surface, a table processing unit to which a processing member for processing the chuck table is mounted and that processes the holding member by bringing the processing member into contact with the holding surface of the chuck table, a moving mechanism that moves the chuck table and the table processing unit relative to each other, and a controller that controls operations of at least the table processing unit and the moving mechanism. The controller controls the moving mechanism such that, when the holding member is processed by the table processing unit, the holding surface has an outer peripheral protruding shape in which, relative to an extended surface of a surface formed by a central region which is a portion of the holding surface including a center thereof, at least a part of an outer peripheral region that is on an outer side of the central region is protruding in a direction transverse to the extended surface.

According to the still further aspect of the present invention, preferably, the controller rotates the processing member along the holding surface such that a rotational diameter in a direction along the holding surface is smaller than a minimum width of the holding surface, while rotating the chuck table about the rotational axis, moves the chuck table and the processing member relative to each other in the direction along the holding surface and in a direction transverse to the holding surface, while bringing the processing member into contact with the holding surface, and thereby processes at least a part of a portion that forms the outer peripheral region of the holding surface in the holding member, such that the holding surface formed by the holding member has the outer peripheral protruding shape.

According to the still further aspect of the present invention, preferably, the controller rotates the processing member along the holding surface such that a rotational diameter in a direction along the holding surface is smaller than a minimum width of the holding surface, while rotating the chuck table about the rotational axis, moves the chuck table and the processing member relative to each other in the direction along the holding surface, while bringing the processing member into contact with the holding surface, and at that time, changes a rotational speed of one of or both the chuck table and the processing member, and thereby processes at least a part of a portion that forms the outer peripheral region of the holding surface in the holding member, such that the holding surface formed by the holding member has the outer peripheral protruding shape.

According to the still further aspect of the present invention, preferably, the processing apparatus further includes a workpiece processing unit that has a spindle to which grindstones are mounted and that processes a workpiece held on the holding surface of the chuck table, and the table processing unit rotates the grindstones or a polishing pad mounted as the processing member by a rotational diameter smaller than a minimum width of the holding surface.

The processing method of a chuck table, the manufacturing method of a processed chuck table, the processing method of a workpiece, the manufacturing method of a processed wafer, and the processing apparatus according to the aspects of the present invention process the holding member that forms the holding surface of the chuck table and form an outer peripheral protruding shape on the holding surface. When a polygonal workpiece is processed with use of a chuck table (processed chuck table) including a holding member in which an outer peripheral protruding shape is formed on the holding surface thereof, uneven thickness that occurs in the polygonal wafer that has been processed can be reduced.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating an example of a form of a processing apparatus;

FIG. 2 is a cross sectional view illustrating a manner of performing grinding processing on a workpiece (wafer) by the processing apparatus illustrated in FIG. 1;

FIG. 3 is a perspective view schematically illustrating an example of a shape formed on a face side of the workpiece (wafer) by grinding processing;

FIG. 4A is a schematic view illustrating an example of a positional relation between the workpiece and grindstones during grinding and a view illustrating a state in which a path followed by the grindstones passes through regions along diagonal lines of the workpiece;

FIG. 4B is a schematic view illustrating another example of a positional relation between the workpiece and the grindstones during grinding and a view illustrating a state in which the path followed by the grindstones passes through regions along line segments that connect intermediate points of opposite sides of the workpiece;

FIG. 5 is a flowchart illustrating an example of steps related to a processing method of a chuck table, a manufacturing method of a processed chuck table, a processing method of a workpiece, and a manufacturing method of a processed wafer;

FIG. 6 is a perspective view schematically illustrating a manner in which a holding member of the chuck table is processed in a holding member processing step;

FIG. 7 is a front cross sectional view schematically illustrating an example of a state in which a portion that forms a central region of a holding surface in the holding member is processed in the holding member processing step;

FIG. 8 is a front cross sectional view schematically illustrating an example of a state in which a portion that forms an outer peripheral region of the holding surface in the holding member is processed in the holding member processing step;

FIG. 9A is a front cross sectional view schematically illustrating an example of a state of a wafer or a processed wafer as a workpiece held on the chuck table;

FIG. 9B is a front cross sectional view schematically illustrating an example of a form of a workpiece (processed wafer) that has been processed and removed from the chuck table; and

FIG. 10 is a perspective view schematically illustrating an example of a movement of a table processing unit relative to the chuck table in the holding member processing step.

### DETAILED DESCRIPTION OF THE PREFERRED EMBODIMENT

An embodiment of the present invention is hereinafter described in detail with reference to the attached drawings.

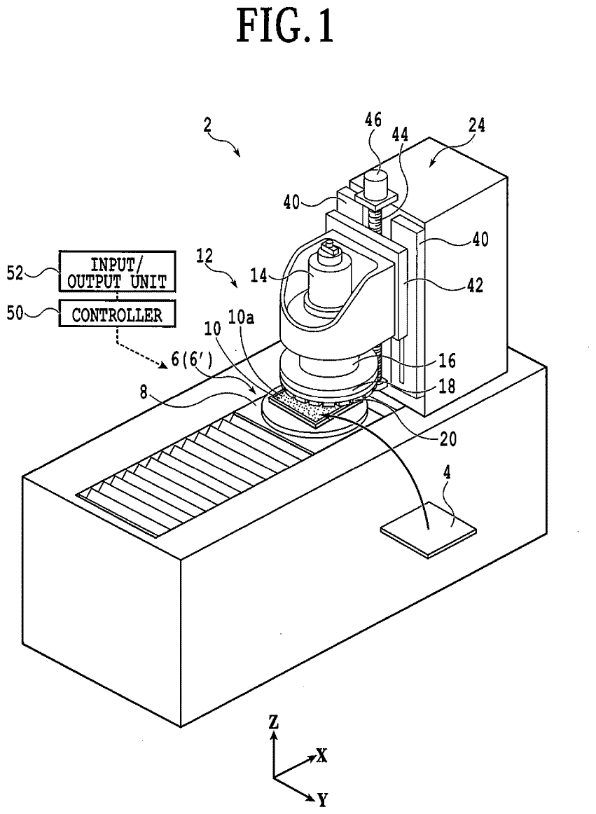

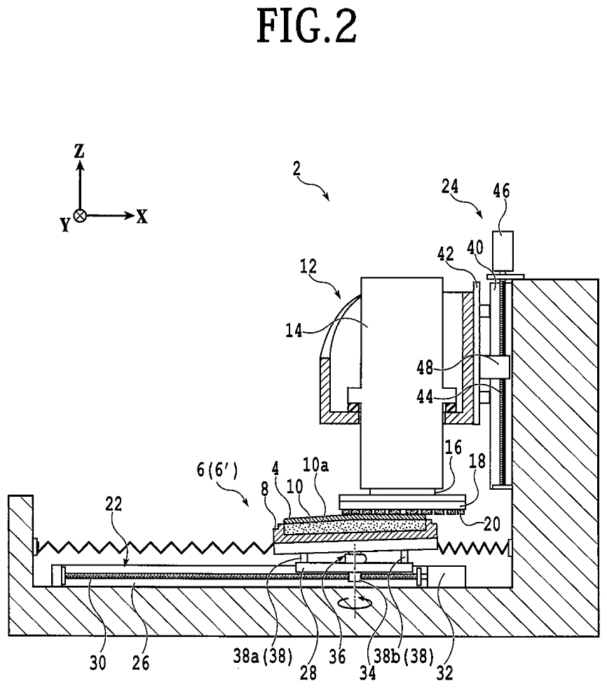

FIG. 1 is a perspective view illustrating an example of a form of a processing apparatus. FIG. 2 is a cross sectional view illustrating a manner of performing grinding processing on a workpiece (wafer) 4 by the processing apparatus illustrated in FIG. 1 and denoted by 2.

In FIGS. 1 and 2, an X-axis direction, a Y-axis direction, and a Z-axis direction represent directions of three axes that are orthogonal to one another in a three dimensional space. The X-axis direction (front-back direction) and the Y-axis direction (left-right direction) are horizontal directions orthogonal to each other. The Z-axis direction (up-down direction) is a direction orthogonal to the X-axis direction and the Y-axis direction and is a vertical direction.

Note that, while such expressions as “along the Z-axis direction” and “along the XY plane” are used in the present specification, these expressions do not necessarily refer only to cases where the orientation of a member or surface precisely coincides with or is parallel to the axis or plane. These expressions also refer to, for example, cases where the member or surface and the axis or plane are oriented in substantially the same direction with slight inclinations and cases where the angle of the member, axis, movement direction, and the like has the component of the relevant direction.

Moreover, also in cases where one extends linearly and the other, on the whole, extends in a direction along the linear direction formed by the one, while forming a curved line around the straight line formed by the one, such an expression as the other is along the one may be used.

The wafer 4 that is a workpiece to be handled as a target of grinding processing in the processing apparatus 2 is, for example, a plate-shaped wafer formed of silicon and is formed in a polygonal shape (in the illustrated example, a rectangular (square) shape) as a whole.

On one side of the wafer 4, such devices as ICs and LSI circuits, for example, are formed.

Note that there are no limitations on the type, material, shape, structure, size, and the like of the wafer 4 as a workpiece. For example, the wafer 4 may be a substrate (wafer) made of a semiconductor other than silicon (GaAs, InP, GaN, SiC, etc.), sapphire, glass, ceramics, resin, or metal. Moreover, there are no limitations on the type, number, shape, structure, size, arrangement, and the like of the devices to be formed on the wafer 4. Devices may not be formed on the wafer 4.

The processing apparatus 2 includes a chuck table 6, a processing unit 12, and moving mechanisms (an X moving mechanism 22 and a Z moving mechanism 24).

The chuck table 6 is a mechanism that holds the wafer 4 which is a plate-shaped workpiece. The chuck table 6 includes a table main body section 8 formed of ceramics, metal, or the like and a holding member 10.

The holding member 10 is, for example, a member formed of porous ceramics, and is formed in a shape (in the illustrated example, a square shape) corresponding to the shape of the wafer 4 to be held.

On an upper portion of the table main body section 8, a recessed portion of a shape (square shape) corresponding to the size of the holding member 10 is formed, and the holding member 10 is fitted and fixed to the recessed portion. Formed inside the table main body section 8 is a flow channel (not illustrated) one end of which is connected to a lower surface of the holding member 10.

The other end of the flow channel provided inside the table main body section 8 is connected to a suction source (not illustrated) such as an ejector, and when the suction source is operated, the negative pressure supplied in the flow channel is caused to act on an object such as the wafer 4 placed on an upper surface 10a of the holding member 10. In this way, the upper surface 10a of the holding member 10 functions as a holding surface that holds the wafer 4 as the workpiece. Note that the holding member 10 may be a plate-shaped member that is formed of metal or the like and includes a plurality of holes vertically penetrating the holding member 10, for example.

As illustrated in FIG. 2, the upper surface of the holding member 10 that functions as the holding surface 10a of the chuck table 6 is formed in a conical surface shape whose central portion is slightly protruding outward (a side opposite the table main body section 8; upward). A bottom face (a side facing the table main body section 8) of the holding member 10 is substantially flat.

Note that, in FIG. 2, the incline of the holding surface (upper surface) 10a is illustrated in an exaggerated manner, and in practice, this incline may be so small that it is invisible to the naked eye. As one example of a specifical value, in a case where the diameter of the holding member 10 is approximately 500 mm, a height difference between a central portion and an outer peripheral portion of the holding member 10 is approximately 50 μm at maximum.

When being held under suction on the conical surface-shaped holding surface 10a, the plate-shaped wafer 4 forms a conical surface shape along the holding surface 10a in cross sectional view as illustrated in FIG. 2, and its central portion slightly protrudes upward to form an apex of the conical surface.

In a space above the chuck table 6, a processing unit 12 as a workpiece processing unit for processing the wafer 4 held on the chuck table 6 is disposed.

The processing unit 12 as the workpiece processing unit includes a spindle housing 14 and a spindle 16 as a rotor housed in the spindle housing 14. The spindle 16, which is a cylindrical member, is supported to be rotatable with respect to the spindle housing 14 about an axis provided in such a manner as to extend along the vertical direction (Z-axis direction).

The spindle 16 has a lower end side exposed from the spindle housing 14 and a lower end portion having a distal end to which a disk-shaped wheel mount is fixed. The wheel mount has a lower surface to which a disk-shaped grinding wheel 18 having substantially the same diameter as the wheel mount is mounted. The grinding wheel 18 has a lower surface to which a plurality of grindstones 20 are fixed throughout the whole circumference. In this manner, the grindstones 20 are attached to the spindle 16 as the component of the grinding wheel 18.

Note that, in the present specification, such members as the grinding wheel 18 and the grindstones 20 that are attached to the processing unit 12 to apply such processing as grinding to the target (here, the wafer 4 as the workpiece) are called a “processing member” as appropriate.

Each of the grindstones 20 attached to the grinding wheel 18 is a grinding stone having a configuration in which abrasive grains are embedded in a bonding material, for example. The bonding material is, for example, a resin bond, a vitrified bond, a metal bond, or the like. In the bonding material, abrasive grains of diamond, cubic boron nitride, or the like are dispersed.

The spindle 16 has an upper end side to which a rotary drive source (not illustrated) such as a motor is coupled and is hence able to rotate together with the grinding wheel 18. When the spindle 16 rotates by operation of the rotary drive source, the grindstones 20 attached to the lower surface of the grinding wheel 18 rotate while drawing a circular ring-shaped path around the rotational axis, and the lower ends of the grindstones 20 form a circular ring-shaped grinding surface. The orientation of the grinding surface formed by the grindstones 20 in association with the rotation is along the orientation of the holding surface 10a of the chuck table 6.

Note that, while the grinding surface formed by the lower ends of the grindstones 20 forms a plane substantially transverse to the rotational axis of the spindle 16, the holding surface 10a of the chuck table 6 forms a conical surface shape as described above, so that the orientation of the grinding surface of the grindstones 20 and the orientation of the holding surface 10a of the chuck table 6 do not precisely coincide with each other.

The chuck table 6 and the processing unit 12 are respectively moved by the X moving mechanism 22 and the Z moving mechanism 24 that are each a moving mechanism.

The X moving mechanism 22 in the processing apparatus 2 according to the present embodiment moves the chuck table 6 along the X-axis direction. The Z moving mechanism 24 moves the processing unit 12 along the Z-axis direction.

The X moving mechanism 22 includes guide rails 26, a moving table 28, a ball screw 30, and a rotary drive source 32.

The guide rails 26 are a pair of rod-shaped members that are fixed to an upper surface of a base of the processing apparatus 2 and that are extending in parallel with each other along the X-axis direction. FIG. 2 illustrates only one of the pair of guide rails 26. To an upper surface of the pair of guide rails 26, the moving table 28 forming a plane along the horizontal plane (XY plane) is attached in a slidable manner along a longitudinal direction of the guide rails 26.

Between the pair of guide rails 26 extending in parallel with each other, a ball screw 30 is disposed along the X-axis direction in parallel with the guide rails 26. On a lower surface side of the moving table 28, a nut portion 34 is provided, and the ball screw 30 is coupled to the nut portion 34 in a rotatable manner via a ball (not illustrated).

To one end portion of the ball screw 30, the rotary drive source 32 that is a pulse motor or the like is coupled. By operation of the rotary drive source 32, the ball screw 30 rotates about its axis, and the moving table 28 moves in the longitudinal direction (direction along the X-axis direction) of the guide rails 26.

On an upper surface of the moving table 28, a rotation unit 36 and an inclination adjustment unit 38 are mounted together with the chuck table 6. The rotation unit 36 is a mechanism that rotates the chuck table 6. The inclination adjustment unit 38 is a mechanism that adjusts the angle of the chuck table 6.

On a lower portion of the table main body section 8 of the chuck table 6, a rotational shaft extending downward from the bottom face of the table main body section 8 along the direction transverse to the holding surface 10a is provided. The rotation unit 36 includes a rotary drive source that is a motor or the like, a driving pulley fixed to an output shaft of the rotary drive source, a driven pulley fixed to the rotational shaft of the chuck table 6, and an endless belt wound around the driving pulley and the driven pulley (none of which are illustrated).

When the rotary drive source of the rotation unit 36 operates, its rotational force is transmitted to the chuck table 6 via the output shaft, the driving pulley, the endless belt, and the driven pulley, and the chuck table 6 rotates about an axis passing through the center of the conical surface formed by the holding surface 10a. While the rotational axis of this rotation extends along the vertical direction (Z-axis direction), the precise angle of the rotational axis with respect to the vertical direction (Z-axis direction) is adjusted by the inclination adjustment unit 38 described below.

The chuck table 6 is supported by the inclination adjustment unit 38 on an upper surface of the moving table 28. The inclination adjustment unit 38 includes one fixed shaft 38a and a plurality of movable shafts 38b each extending along the Z-axis direction. Note that FIG. 2 illustrates only one movable shaft 38b.

The movable shaft 38b is configured to be extendable and shrinkable along the Z-axis direction, so that the chuck table 6 can be inclined on the moving table 28 or adjusted in angle.

At a position on the rear side (right side in FIG. 2) of the X moving mechanism 22 and the chuck table 6 in the base of the processing apparatus 2, a protruding portion protruding upward from the upper surface of the base is provided. To a front surface of the protruding portion, the processing unit 12 is attached via the Z moving mechanism 24.

The Z moving mechanism 24 includes guide rails 40, a moving table 42, a ball screw 44, and a rotary drive source 46.

The guide rails 40 are a pair of rod-shaped members that are fixed to the front surface of the protruding portion of the base and that are extending in parallel with each other along the Z-axis direction. FIG. 2 illustrates only one of the pair of guide rails 40. To the front surface of the pair of guide rails 40 (the surface opposite the surface which is attached to the protruding portion of the base), the moving table 42 forming the plane along the vertical plane (YZ plane) is attached in a slidable manner along the longitudinal direction of the guide rails 40.

Between the pair of guide rails 40 extending in parallel with each other, a ball screw 44 is disposed in parallel with the guide rails 40 along the Z-axis direction. To a reverse side (rear surface) of the moving table 42, a nut portion 48 is provided, and the ball screw 44 is coupled to the nut portion 48 in a rotatable manner via a ball (not illustrated).

To one end portion of the ball screw 44, the rotary drive source 46 that is a pulse motor or the like is coupled. By operation of the rotary drive source 46, the ball screw 44 rotates about its axis, and the moving table 42 moves in the longitudinal direction (the direction along the Z-axis direction) of the guide rails 40.

Note that each of the X moving mechanism 22 and the Z moving mechanism 24 functioning as a moving mechanism is a mechanism that moves the chuck table 6 and the processing unit 12 relative to each other. The specific movement to be made by each moving mechanism may be set as appropriate within such a scope that the movement of each unit that is necessary for the steps of processing can suitably be performed.

For example, the X moving mechanism 22 may move the processing unit 12 instead of moving the chuck table 6 and thereby cause the two members to move relative to each other. Alternatively, the X moving mechanism 22 may move both the chuck table 6 and the processing unit 12.

Similarly, the Z moving mechanism 24 may move the chuck table 6 instead of moving the processing unit 12 and thereby cause the two members to move relative to each other. Alternatively, the Z moving mechanism 24 may move both the chuck table 6 and the processing unit 12.

The processing apparatus 2 further includes a processing liquid supply unit (not illustrated). The processing liquid supply unit is, for example, a nozzle that discharges water as processing liquid, and supplies water to the wafer 4 and the grindstones 20 when grinding processing is performed on the wafer 4. The processing liquid supply unit which is a nozzle has its discharge port provided above the holding surface 10a of the chuck table 6, for example. Note that a processing liquid supply unit having such a mechanism for supplying processing liquid through the processing unit 12 may be included in the processing apparatus 2.

A controller 50 illustrated in FIG. 1 is connected to the units (the chuck table 6, the processing unit 12, the moving mechanisms (the X moving mechanism 22 and the Z moving mechanism 24), the rotation unit 36, the inclination adjustment unit 38, and others) configuring the processing apparatus 2. The controller 50 according to the present embodiment is a mechanism that monitors and controls the operation of the units of the processing apparatus 2 and includes, for example, a computer.

The computer included in the controller 50 has, for example, an information processing apparatus that performs various kinds of information processing and a storage apparatus that stores information. The information processing apparatus is, for example, a central processing unit (CPU). The storage apparatus includes, for example, a main storage apparatus such as a dynamic random access memory (DRAM) and an auxiliary storage apparatus such as a hard disk drive and a flash memory. The functions of the controller 50 are implemented by, for example, the information processing apparatus operating in accordance with the program (software) stored in the storage apparatus.

To the controller 50, an input/output unit 52 for displaying various kinds of information related to operation of the processing apparatus 2 and inputting operation commands to each unit is connected.

The input/output unit 52 is, for example, a display of a touch panel type. On the input/output unit 52, an operation screen for inputting various kinds of information, commands, and the like for each unit of the processing apparatus 2 is displayed, and an operator can input information to the controller 50 by a touch operation on the operation screen. Note that an apparatus for displaying various kinds of information and an apparatus for inputting operations may be provided separately from each other, and for example, the input/output unit 52 may include a liquid crystal display connected to the controller 50 and an input apparatus such as a mouse and a keyboard similarly connected to the controller 50.

In a case where the grinding processing of the wafer 4 is to be performed by the processing apparatus 2 described above, first, as illustrated in FIG. 2, the wafer 4 is held on the holding surface 10a of the chuck table 6. Specifically, the wafer 4 is placed on the holding surface 10a that is the upper surface of the holding member 10, a negative pressure is supplied to the holding member 10 from the suction source (not illustrated), and the wafer 4 is held under suction on the holding surface 10a.

As illustrated in FIG. 2, the holding surface 10a of the chuck table 6 has a conical surface shape, and an upper surface side (the surface on the side opposite the surface that is to be held under suction on the holding surface 10a) of the wafer 4 to be held on the holding surface 10a also has a conical surface shape.

Next, the chuck table 6 and the processing unit 12 are moved by the respective moving mechanisms (the X moving mechanism 22 and the Z moving mechanism 24) to be positioned relative to each other such that a part of a circular-ring shaped path drawn by the grindstones 20 in association with the rotation of the spindle 16 overlaps the apex of the conical surface formed by the holding surface 10a and the wafer 4 in plan view (view as seen in the Z-axis direction; more accurately, view along the direction of relative movement of the chuck table 6 and the processing unit 12 by the Z moving mechanism 24).

From this state, the chuck table 6 and the spindle 16, while each rotating, approach each other along the Z-axis direction by the operation of the Z moving mechanism 24. When the grindstones 20 of the grinding wheel 18 attached to the spindle 16 of the processing unit 12 come into contact with the upper surface of the wafer 4 held on the chuck table 6, grinding of the wafer 4 starts. When grinding processing is performed, water as processing liquid is supplied from the processing liquid supply unit (not illustrated).

While grinding is performed, the processing unit 12 is gradually moved (grinding fed) downward along the Z-axis direction by the Z moving mechanism 24 such that the chuck table 6 and the spindle 16 approach each other.

When grinding is performed, the rotational axis of the chuck table 6 and the rotational axis of the spindle 16 are in such a positional relation to extend along each other (yet, the rotational axis of the chuck table 6 is slightly inclined relative to the Z axis, and the two rotational axes are not precisely parallel to each other). When grinding feeding is performed, in association with the wearing of the wafer 4 and the grindstones 20, the chuck table 6 and the spindle 16 are moved relative to each other by the Z moving mechanism 24 in such a manner as to approach each other in a direction along the rotational axis of the spindle 16 (direction along the Z-axis direction).

Note that, in a case where the processing apparatus 2 described above is used, the spindle 16 and the chuck table 6 move relative to each other in the direction along the Z-axis direction by the spindle 16 moving along the Z-axis direction, but instead of the spindle 16, the chuck table 6 may move, or both the chuck table 6 and the spindle 16 may move.

The path followed by the lower ends of the rotating grindstones 20 forms a circular ring-shaped grinding surface of a width of the grindstones 20 (the size related to the radial direction of the grinding wheel 18) in the direction along the horizontal plane (XY plane).

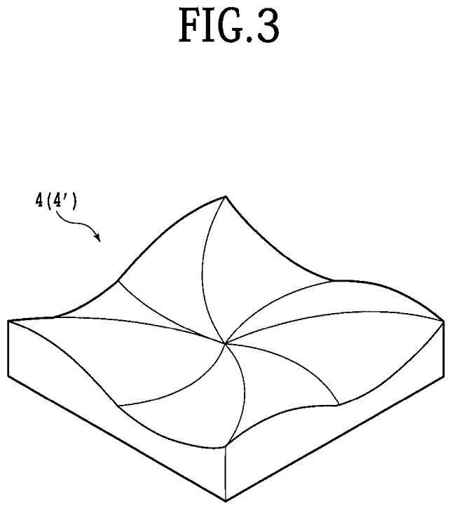

On the face side (upper surface) of the wafer 4 that has been ground by the steps described above (the processed wafer 4′), for example, the shape illustrated in FIG. 3 is sometimes formed.

As illustrated in FIG. 3, on the face side of the wafer 4 that has been processed (the processed wafer 4′), regions along the diagonal lines in the face side forming a rectangular shape as a whole are protruding upward (toward the processing unit 12 side with respect to the plane formed by the upper surface of the wafer 4 at the time of grinding) relative to the regions along the line segments connecting the intermediate points of the opposite sides. Moreover, among the regions along the diagonal lines, the regions closer to the corners are protruding upward relative to the regions closer to the center.

Note that FIG. 3 illustrates the thickness of the wafer 4 (processed wafer 4′) and the irregularities formed on the face side thereof in an exaggerated manner, but in reality, the irregularities formed on the face side of the processed wafer 4′ are so minute that they are invisible to the naked eye. As one example of a specific numerical value, in a case where one side of the wafer 4 (processed wafer 4′) is approximately 500 mm, the height difference in the irregularities formed on the face side is approximately 15 μm at maximum.

Such a shape is formed due to the size of the area of contact (contact area) between the grindstones 20 and the wafer 4 during grinding. If the force applied to the two members along the direction orthogonal to the contact surface, the rotational speed of the two members, or the like is constant when grinding is performed, the smaller the contact area is, the more easily the wafer 4 is ground, while the larger the contact area is, the less easily the wafer 4 is ground.

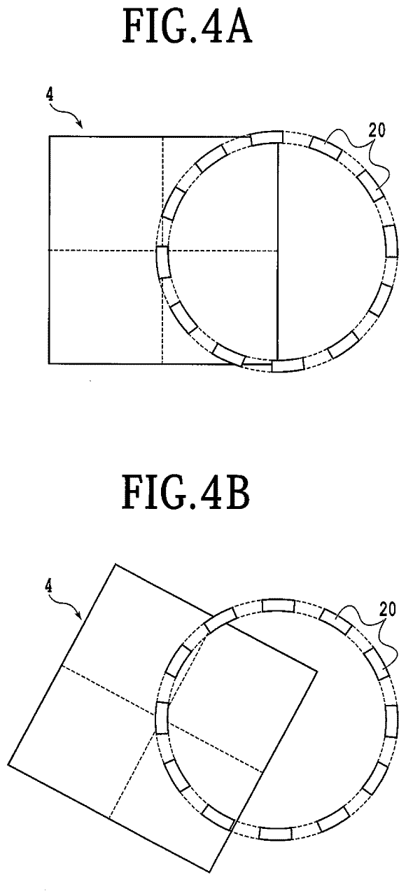

FIG. 4A and FIG. 4B are each a schematic view illustrating an example of a positional relation between the workpiece (wafer) 4 and the grindstones 20 during grinding. FIG. 4A illustrates a state in which the path followed by the grindstones 20 passes through the regions along the diagonal lines of the workpiece (wafer) 4. FIG. 4B illustrates a state in which the path followed by the grindstones 20 passes through the regions along the line segments (which are depicted by a broken line in the figure) that connect the intermediate points of the opposite sides of the workpiece (wafer) 4.

In the example illustrated in FIGS. 4A and 4B, the plate-shaped wafer 4 forming a rectangular (square) shape in plan view is ground when the wafer 4 is rotating and the grindstones 20 rotating while drawing a circular ring-shaped path come into contact with the rotating wafer 4. The rotational diameter of the grindstones 20 is substantially the same as the length of one side of the wafer 4 forming a substantially square shape in plan view, and the path followed by the grindstones 20 passes through the center of the square-shaped wafer 4 during grinding.

Note that, when grinding is performed, the wafer 4 has a conical surface shape in cross sectional view as illustrated in FIG. 2. Hence, in a state in which the wafer 4 is ground while the path followed by the grindstones 20 and the wafer 4 overlap each other in plan view as illustrated in FIGS. 4A and 4B, the region to be ground in the upper surface of the wafer 4 is approximately half the portion of the wafer 4 that overlaps with the path followed by the grindstones 20 (a region corresponding to a portion of the wafer 4 that overlaps with the path followed by the grindstones 20 from the center of the wafer 4 to a point of intersection with one side or a vertex). This is because the surface formed by the upper surface of the wafer 4 is a curved surface (conical surface), while the surface ground by the grindstones 20 is a substantially flat surface.

While grinding is performed, the rectangular wafer 4 rotates together with the chuck table 6, so that the positional relation between the wafer 4 and the grindstones 20 in plan view varies according to the rotation angle of the chuck table 6. That is, at a certain timing, the path followed by the grindstones 20 passes through the region along the diagonal line of the wafer 4 as illustrated in FIG. 4A, while at another timing, the path followed by the grindstones 20 passes through the region along the line segment connecting the intermediate points of the opposite sides of the wafer 4 as illustrated in FIG. 4B.

The area of contact between the grindstones 20 and the wafer 4 in the state illustrated in FIG. 4A is larger than the area of contact between the two members in the state illustrated in FIG. 4B. Hence, in the state illustrated in FIG. 4A, the wafer 4 is less easily ground than in the state illustrated in FIG. 4B, and the grinding amount of the wafer 4 in the state illustrated in FIG. 4A is smaller than the grinding amount of the wafer 4 in the state illustrated in FIG. 4B. This forms the shape illustrated in FIG. 3 on the wafer 4 that has been ground (the processed wafer 4′).

If the lower surface (the surface opposite the face side on which the irregularities illustrated in FIG. 3 are formed) of the processed wafer 4′ is flat, the processed wafer 4′ having such a shape will have an uneven thickness, possibly leading to variation in the thickness of the chips obtained by the processed wafer 4′ being divided, for example.

In order to reduce such unevenness in the thickness of the processed wafer 4′ as described above, one effective solution is to form in advance a shape similar to the shape formed on the face side of the wafer 4 that has been processed (the processed wafer 4′), on the holding surface 10a of the chuck table 6 that holds the wafer 4, when grinding is performed. An apparatus and a method for forming such a shape on the holding surface 10a of the chuck table 6 are described below.

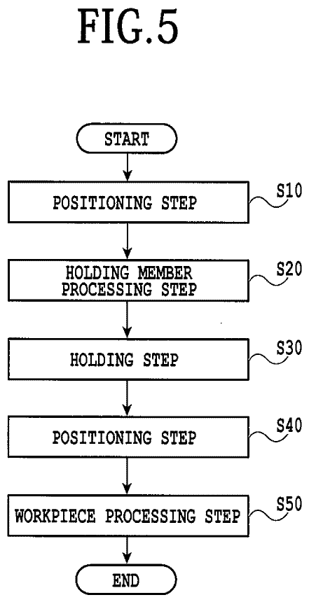

FIG. 5 is a flowchart describing an example of steps related to a processing method of a chuck table, a manufacturing method of a processed chuck table, a processing method of a workpiece, and a manufacturing method of a processed wafer. The steps illustrated in FIG. 5 include a positioning step S10, a holding member processing step S20, a holding step S30, a positioning step S40, and a workpiece processing step S50.

Among these steps, at least some of the steps are performed by the controller 50 (see FIG. 1) in accordance with a program, for example.

Among the steps illustrated in FIG. 5, in the holding member processing step S20, the holding member 10 that forms the holding surface 10a of the chuck table 6 is processed before the wafer 4 as the workpiece is subjected to grinding processing (workpiece processing step S50).

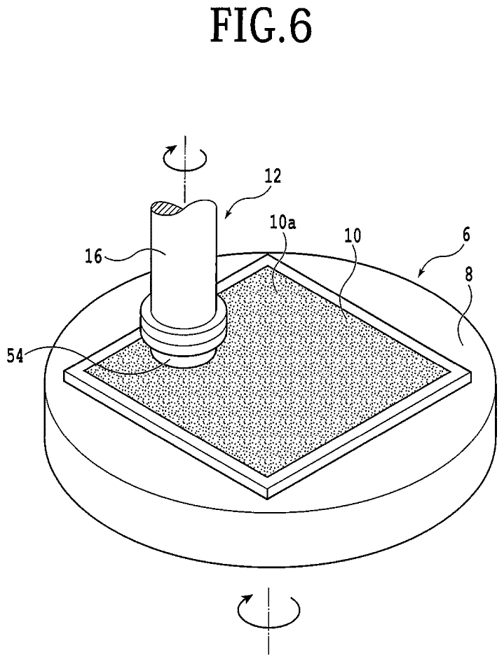

FIG. 6 is a perspective view schematically illustrating a manner in which the holding member 10 of the chuck table 6 is processed in the holding member processing step S20. The processing of the holding member 10 performed in this step is one kind of what is generally called self grinding. Yet, in the holding member processing step S20 in the steps, the holding member 10 is processed under conditions different from those used at the time of grinding the workpiece (wafer) 4.

Hence, in the processing apparatus 2 illustrated in FIGS. 1 and 2, for example, the grinding wheel 18 mounted to the spindle 16 is replaced with a different processing member. The different processing member may be a grinding wheel including grindstones of a type different from that of the grindstones 20 used at the time of grinding the workpiece (wafer) 4, a grinding wheel having a diameter different from that of the grinding wheel 18 used for grinding the workpiece (wafer) 4, or a polishing pad.

In at least a part of the holding member processing step S20, a processing member whose maximum width is set to be smaller than the minimum width of the holding surface 10a formed by the holding member 10 that is to be processed is preferably used. Moreover, the maximum width of the processing member is preferably set to be smaller than the central region of the holding surface 10a (a portion including the center of the holding surface 10a). In particular, the maximum width of the processing member is preferably set to be smaller than half the width of the central region of the holding surface 10a.

Note that the minimum width of the holding surface 10a referred to here means the length of the shortest line segment among the line segments that pass through the center of the holding surface 10a and that have both ends at the points of intersection with the outer edges (sides or corners) of the holding surface 10a. If the holding surface has a circular shape, the diameter of the circle is the minimum width of the holding surface. In the example illustrated in FIG. 6, the holding surface 10a has a square shape, and hence, the length of one side of the square is the minimum width of the holding surface 10a.

The maximum width of the processing member is a size of a surface of the processing member that may come into contact with the holding surface 10a when processing is performed, and refers to the length of the longest line segment among the line segments that pass through the center of the surface and that have both ends at the points of intersection with the outer edges (sides or corners) of the contact surface. If the processing member has a cylindrical shape and the surface has a circular shape, the diameter of the circle is the maximum width of the processing member. Further, if the processing member is formed as the grinding wheel including the grindstones in a circular ring shape, the diameter of the path drawn by the grindstones is the maximum width of the processing member.

FIG. 6 illustrates the manner in which the rectangular holding member 10 is processed by a polishing pad 54, in a state in which the grinding wheel 18 mounted to the spindle 16 of the processing unit 12 included in the processing apparatus 2 (see FIGS. 1 and 2) is replaced with the polishing pad 54. In this case, the workpiece processing unit 12 for processing the workpiece (wafer) 4 is used as the table processing unit 12 for processing the holding member 10 of the chuck table 6. That is, the table processing unit and the workpiece processing unit are of the same mechanism except that either the grinding wheel 18 or the polishing pad 54 is mounted thereto.

In the positioning step S10 prior to the holding member processing step S20, the chuck table 6 and the processing unit (table processing unit) 12 are moved by the respective moving mechanisms (the X moving mechanism 22 and the Z moving mechanisms 24) to be positioned relative to each other such that at least a part of the polishing pad 54 overlaps the holding surface 10a in plan view (the view as seen in the Z-axis direction).

Specifically, the chuck table 6 rotates about a rotational axis transverse to the holding surface 10a, and the spindle 16 to which the polishing pad 54 is mounted rotates. By operation of the Z moving mechanism 24, the chuck table 6 and the polishing pad 54 approach each other along the Z-axis direction.

When the polishing pad 54 comes into contact with the holding surface 10a of the chuck table 6, the grinding processing of the holding member 10 starts (holding member processing step S20). In a state in which the rotating polishing pad 54 is in contact with the holding surface 10a, the chuck table 6 and the polishing pad 54 are moved relative to each other along the relevant rotational axis direction, and the holding member 10 is processed. At the time of processing, water as the processing liquid is supplied from the processing liquid supply unit (not illustrated).

As illustrated in FIG. 6, this processing is performed by the polishing pad 54 whose maximum width is smaller than the minimum width of the holding surface 10a formed by the holding member 10. In this instance, the holding member 10 is processed such that the holding surface 10a has a specific outer peripheral protruding shape.

The “outer peripheral protruding shape” of the holding surface 10a as described in the present specification is a shape in which, relative to an extended surface of a surface formed by the central region in the holding surface 10a, at least a part of an outer peripheral region, which is on an outer side of the central region, protrudes upward (toward a side where the processing unit 12 is positioned relative to the holding surface 10a and which is on an opposite side of the table main body section 8) in a direction transverse to the extended surface.

The “extended surface of a surface formed by the central region” as referred to in the present specification refers to a surface assumed to be obtained by a surface formed by the central region being extended outward. In a case where the central region has a conical surface shape, the extended surface is a curved surface obtained by the conical surface being extended.

The holding member 10 is processed in a stepwise manner for a portion forming the central region of the holding surface 10a and a portion forming the outer peripheral region. The outer peripheral region is a region located on the outer side of the central region in the holding surface 10a. The position of the boundary between the central region and the outer peripheral region in the holding surface 10a may freely be decided by a person who performs processing of the holding member 10.

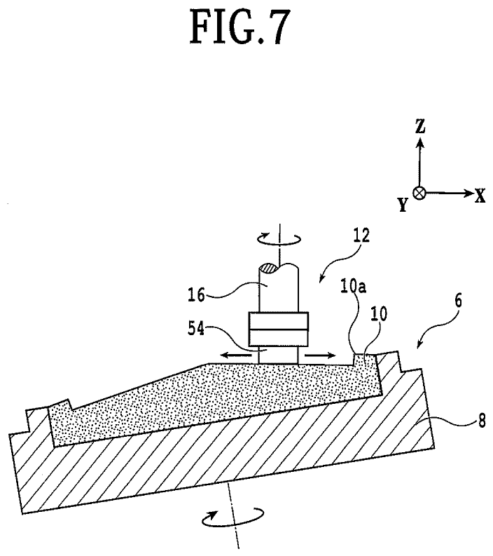

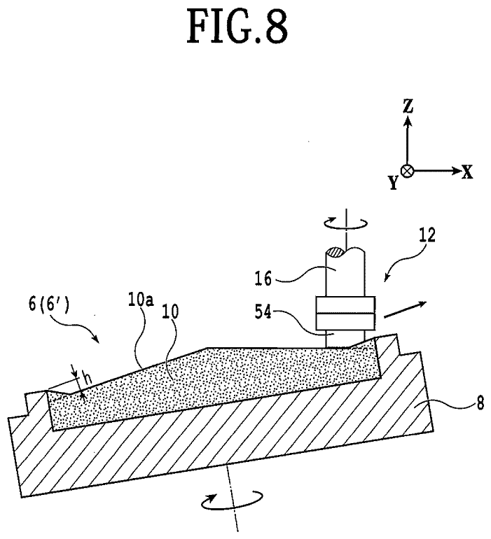

FIG. 7 is a front cross sectional view schematically illustrating an example of a state in which a portion of the holding member 10 forming the central region of the holding surface 10a is processed. FIG. 8 is a front cross sectional view schematically illustrating an example of a state in which a portion of the holding member 10 forming the outer peripheral region of the holding surface 10a is processed.

In the holding member processing step S20, for example, as illustrated in FIG. 7, first, the portion of the holding member 10 forming the central region of the holding surface 10a is processed to reduce the thickness of the holding member 10.

The central region is processed by, for example, the polishing pad 54 rotating about the rotational axis along the Z-axis direction in a direction along the holding surface 10a and coming into contact with the central region of the holding surface 10a formed by the holding member 10, while the chuck table 6 is rotating about the rotational axis along the Z-axis direction.

The maximum width of the polishing pad 54 is set to be smaller than the minimum width of the holding surface 10a. Hence, if the spindle 16 is rotated in a state in which the polishing pad 54 is attached to the spindle 16 in such a manner that the rotational axis of the spindle 16 is aligned with the center of the polishing pad 54, the rotational diameter of the rotational movement of the polishing pad 54 in the direction along the holding surface 10a becomes smaller than the minimum width of the holding surface 10a.

By the chuck table 6 and the polishing pad 54 being moved relative to each other in the direction along the holding surface 10a by the X moving mechanism 22 in a state in which the polishing pad 54 is in contact with the central region of the holding surface 10a, the portion of the holding member 10 forming the central region of the holding surface 10a is ground, as illustrated in FIG. 7.

The holding surface 10a has a conical surface shape as described above (see FIG. 2), and the portion forming the central region is processed by thinly grinding the face side of the holding member 10 to maintain the conical surface shape.

With the portion forming the central region being ground in the manner described above, at least a portion of the outer peripheral region protrudes relative to the extended surface of the surface formed by the central region. That is, the holding surface 10a is formed with the outer peripheral protruding shape described above.

Next, as illustrated in FIG. 8, the outer peripheral region which is on the outer side of the central region is processed, and the outer peripheral protruding shape formed in the holding surface 10a is adjusted. The outer peripheral region is processed by the polishing pad 54 rotating about the rotational axis along the Z-axis direction in the direction along the holding surface 10a and coming into contact with the outer peripheral region of the holding surface 10a formed by the holding member 10, while the chuck table 6 is rotating about the rotational axis along the Z-axis direction, as in the processing of the central region, for example.

As a result, at least a part of the portion that is a part of the holding member 10 and that forms the outer peripheral region of the holding surface 10a is processed, and, for example, as illustrated in FIG. 8, an incline that rises upward from the outer edge of the central region toward the outer side is formed in the outer peripheral region.

In the chuck table 6 illustrated in FIG. 8 (the processed chuck table 6′), the central region of the holding surface 10a is formed in a conical shape, and the outer peripheral region positioned on the outer side of the central region protrudes by a height h at maximum in a direction transverse to (orthogonal to) an extended surface (indicated by a broken line in FIG. 8) of a surface formed by the central region, relative to the extended surface.

Such an outer peripheral protruding portion can be formed by the following method, for example, in addition to the method already described.

First, the processing unit 12 to which the grinding wheel 18 including the grindstones 20 is attached as the processing member as illustrated in FIGS. 1, 2, 4, and 5 grinds the holding member 10 of the chuck table 6. This process substantially corresponds to the self grinding described in Japanese Patent Laid-open No. 2020-55080, and the processing unit 12 functions as the table processing unit in this instance.

As a result, the upper surface (holding surface) 10a of the rectangular holding member 10 is processed into a shape similar to that of the face side of the processed wafer 4′ illustrated in FIG. 3. While this shape is an outer peripheral protruding shape in which a part of the outer peripheral region is protruding relative to the extended surface of the surface formed by the central region, since the holding member 10 and the wafer 4 are formed of different materials, the shape formed on the holding member 10 and the shape formed on the face side of the processed wafer 4′ are not completely the same.

Specifically, the holding member 10 formed with porous ceramics is more easily ground than the wafer 4 formed with silicon, and hence, the shape formed on the holding surface 10a is a shallow shape (shape with a small amount of protrusion of the outer peripheral region relative to the extended surface of the surface formed by the central region) compared to the shape formed on the face side of the wafer 4. In this instance, in a case where one side of the rectangular holding surface 10a is approximately 500 mm, for example, the amount of protrusion of the outer peripheral region relative to the extended surface of the surface formed by the central region in the outer peripheral protruding shape formed on the holding surface 10a is 2 to 8 μm at maximum, for example.

Next, the grinding wheel 18 attached to the processing unit (table processing unit) 12 is replaced with a processing member (the grinding wheel 18 including the grindstones 20 or the polishing pad 54) that has a smaller diameter, that is, has a small maximum width. The processing member replacing the grinding wheel 18 processes the portion of the holding member 10 forming the central region of the holding surface 10a.

With the portion forming the central region being thinly ground (for approximately 2 μm, for example), the amount of protrusion of the outer peripheral region relative to the extended surface of the surface formed by the central region becomes relatively great. Since the amount of protrusion prior to the processing described above is 2 to 8 μm as described above, with the portion forming the central region being ground for approximately 2 μm, the amount of protrusion becomes 4 to 10 μm at maximum, for example.

Here, as a result of the portion forming the central portion being processed, a gap corresponding to the processing amount of the central region is in some cases generated between the central region and the outer peripheral region in the holding surface 10a. This gap may be ignored if it is sufficiently small, but processing may be performed on the surroundings of the gap such that the central region and the outer peripheral region are smoothly connected to each other.

For example, a portion of the outer peripheral region that is near the boundary with the central region is separately processed such that a downward incline toward the central region is formed. When the outer peripheral region is processed in the manner described above, the angle of incline of the outer peripheral region relative to the extended surface of the surface formed by the central region becomes large, offering such an advantage that the uneven thickness of the outer peripheral portion is efficiently corrected in the processed wafer 4′ that is finally formed.

Alternatively, at the time when the central region is processed, the portion near the outer peripheral region may be processed in such a shape to form an incline rising toward the outer peripheral region.

At least a part of processing related to forming the outer peripheral protruding shape as described above is performed by adjusting the distance of the processing unit 12 in the Z-axis direction from the chuck table 6, for example.

At the time of processing, the chuck table 6 and the polishing pad 54 are moved relative to each other in the direction along the holding surface 10a by the X moving mechanism 22 in a state in which the polishing pad 54 is in contact with the holding surface 10a. At this time, the chuck table 6 and the polishing pad 54 are moved relative to each other in the direction transverse to the holding surface 10a (the direction along the Z-axis direction) by the Z moving mechanism 24 according to the relative positions of the chuck table 6 and the polishing pad 54 in the X-axis direction.

Specifically, the polishing pad 54 is adjusted in position in the Z-axis direction in such a manner as to be closer to the chuck table 6 at a portion close to the central region but to be farther from the chuck table 6 at a portion farther from the central region. This forms the outer peripheral protruding shape illustrated in FIG. 8 on the holding surface 10a of the holding member 10.

Alternatively, the outer peripheral protruding shape illustrated in FIG. 8 can be formed by adjusting the rotational speed of the chuck table 6 or the polishing pad 54.

The holding member 10 of the chuck table 6 is ground when the chuck table 6 and the polishing pad 54 rotate while coming into contact with each other. At this time, the holding member 10 is ground more easily as the relative speed between the chuck table 6 and the polishing pad 54 is higher but is ground less easily as the relative speed is lower.

At the time of processing, the chuck table 6 and the polishing pad 54 are moved relative to each other in the direction along the holding surface 10a by each independently rotating in a state in which the polishing pad 54 is in contact with the holding surface 10a. At this time, if the rotational speed of one of or both the chuck table 6 and the polishing pad 54 is changed according to the relative positions of the chuck table 6 and the polishing pad 54 in the X-axis direction, the processing amount (the amount to ground) of the holding member 10 changes according to the position on the holding member 10. Such a method can also form the outer peripheral protruding shape illustrated in FIG. 8 on the holding surface 10a of the holding member 10.

Note that the order of processing the central region and the outer peripheral region does not necessarily have to be the order of processing the outer peripheral region after the central region is processed, and, for example, processing of the central region and processing of the outer peripheral region may alternately or parallelly be performed, or the processing of the central region and the processing of the outer peripheral region may be performed as a series of steps.

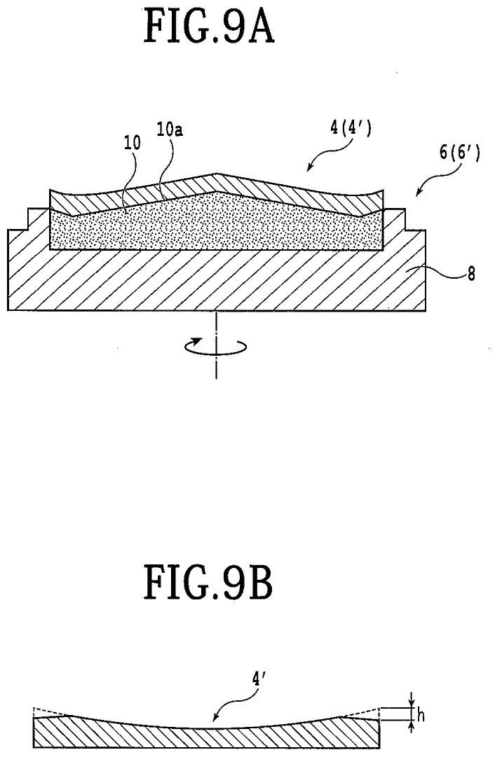

By the steps described above, the holding member 10 of the chuck table 6 is processed, and the processed chuck table 6′ is manufactured. Note that, in FIGS. 7 and 8, the height difference between the central region and the outer peripheral region in the holding surface 10a is illustrated in an exaggerated manner, but this difference is in practice so small that it is invisible to the naked eye. As one example of a specific numerical value, in a case where one side of the holding member 10 is approximately 500 mm, the height difference (height h) formed between the surface formed by the central region of the holding surface 10a and the outer peripheral region is approximately 10 μm (several μm to several dozen μm). Moreover, the conical surface formed by the central region is also illustrated in an exaggerated manner as in FIG. 2. This also applies to FIG. 9 mentioned below.

After the holding member 10 of the chuck table 6 has been processed to have the outer peripheral protruding shape as described above, the processing member is replaced with the grinding wheel 18 for processing the workpiece (wafer) 4, and the processing unit 12 as the table processing unit is converted into the processing unit 12 as the workpiece processing unit.

Next, the holding step S30 is performed, and thereafter, the positioning step S40 and the workpiece processing step S50 are performed. The steps from the holding step S30 to the workpiece processing step S50 are similar to those described above.

As illustrated in FIG. 2, first, a plate-shaped, polygonal workpiece (wafer) 4 is held on the holding surface 10a formed by the holding member 10 of the chuck table 6 (processed chuck table 6′) (holding step S30).

Next, the chuck table 6 (processed chuck table 6′) and the processing unit 12 are moved by the respective moving mechanisms (the X moving mechanism 22 and the Z moving mechanism 24) to be positioned relative to each other such that a part of the path followed by the grindstones 20 overlaps the holding surface 10a (positioning step S40).

Subsequently, the chuck table 6 (processed chuck table 6′) rotates about the rotational axis transverse to the holding surface 10a, and the grinding wheel 18 to which the grindstones 20 are mounted rotates by rotation of the spindle 16. By operation of the Z moving mechanism 24, the processed chuck table 6′ holding the wafer 4 and the spindle 16 to which the grinding wheel 18 is attached approach each other along the Z-axis direction.

When the grindstones 20 come into contact with the upper surface of the wafer 4, the grinding processing of the wafer 4 starts. The chuck table 6 (processed chuck table 6′) and the grinding wheel 18 are moved relative to each other along the rotational axis direction in a state in which the rotating grindstones 20 are in contact with the workpiece (wafer) 4 held on the holding surface 10a, and the workpiece (wafer) 4 is ground (workpiece processing step S50).

At the time of grinding, water as processing liquid is supplied from the processing liquid supply unit (not illustrated). When the wafer 4 is ground to a desired thickness, the workpiece processing step S50 ends.

By the steps described above, the wafer 4 as the workpiece is processed, and the processed wafer 4′ is manufactured as illustrated in FIGS. 9A and 9B.

FIG. 9A is a front cross sectional view schematically illustrating an example of a state of the wafer 4 or the processed wafer 4′ as the workpiece held on the chuck table 6 (processed chuck table 6′). FIG. 9B is a front cross sectional view schematically illustrating an example of a form of the workpiece (processed wafer) 4′ that has been subjected to grinding processing and removed from the chuck table 6 (processed chuck table 6′).

In a case where grinding processing of the rectangular wafer 4 is performed by the abovementioned method, for example, the irregularities illustrated in FIG. 3 are formed on the face side of the wafer 4 that has been processed (processed wafer 4′).

FIG. 9A illustrates a state in which the processed wafer 4′ is held on the chuck table 6 (processed chuck table 6′) immediately after grinding processing of the wafer 4 has been performed. While the irregularities illustrated in FIG. 3 are formed on the face side (upper surface) of the processed wafer 4′, the reverse side (lower surface) of the processed wafer 4′ that is in contact with the holding surface 10a (of the processed chuck table 6′) has a shape corresponding to the outer peripheral protruding shape formed on the holding surface 10a.

That is, a portion that is a part of the lower surface of the processed wafer 4′ and that corresponds to the outer peripheral region of the holding surface 10a (a region including the corner portion) has a shape extending upward while forming an incline (here, this shape is called an “outer peripheral thinned shape” for the sake of convenience). When the processed wafer 4′ formed in such a shape is placed on a flat plane, the processed wafer 4′ has the shape illustrated in FIG. 9B.

In this instance, if the outer peripheral thinned shape described above is not formed on the lower surface side of the processed wafer 4′, the processed wafer 4′ would have a thick outer peripheral portion as illustrated by a broken line in FIG. 9B. That is, in the processed wafer 4′, the thickness would be uneven between the central portion and the outer peripheral portion.

Here, if the outer peripheral thinned shape is formed on the lower surface of the wafer 4, the processed wafer 4′ would have the shape illustrated by a solid line in FIG. 9B, and the uneven thickness would be reduced. That is, at a portion held on the outer peripheral region of the holding surface 10a, the processed wafer 4′ is formed to be thin by an amount corresponding to the outer peripheral protruding shape formed on the holding surface 10a (by an amount equivalent to the height h at maximum), reducing the difference in thickness between the central portion and the outer peripheral portion.

If the holding member 10 forming the holding surface 10a of the chuck table 6 is processed such that the holding surface 10a is formed to have the outer peripheral protruding shape before the grinding processing of the wafer 4 is performed, the processed chuck table 6′ including the holding member 10 having such a shape can be used to hold the workpiece (wafer) 4 thereon and perform grinding processing on the workpiece (wafer) 4 to thereby correct the uneven thickness in the wafer 4 that has been processed (the processed wafer 4′).

Note that, in the above description, as the outer peripheral protruding shape formed on the holding surface 10a of the chuck table 6 (processed chuck table 6′), a shape in which an incline rising from the edge of the central region toward the outer side is formed in the outer peripheral region has been described (see FIG. 8). Here, in a case where the central region has a conical shape and the holding surface 10a is formed in a simple shape in which an inclined surface as an outer peripheral region extends in an inverted conical shape from the edge of the central region, this outer peripheral protruding shape does not precisely correspond to the shape (see FIG. 3) formed on the face side of the wafer 4 (processed wafer 4′) in the workpiece processing step S50.

However, even if the outer peripheral protruding shape formed on the holding surface 10a of the chuck table 6 (processed chuck table 6′) in the holding member processing step S20 and the shape formed on the face side of the wafer 4 (processed wafer 4′) in the workpiece processing step S50 differ, if the two shapes have in common such a characteristic that “at least a part of the outer peripheral region is protruding relative to the extended surface of the surface formed by the central region,” the uneven thickness in the processed wafer 4′ can be reduced as illustrated in FIG. 9B, for example.

Needless to say, an outer peripheral protruding shape that can correspond at higher accuracy to the shape formed on the face side of the wafer 4 (processed wafer 4′) in the workpiece processing step S50 may be formed on the holding surface 10a of the chuck table 6 (processed chuck table 6′) in the holding member processing step S20.

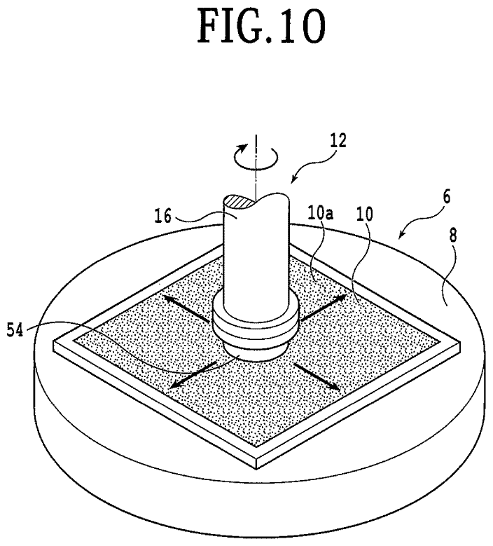

FIG. 10 is a perspective view schematically illustrating an example of a movement of the processing unit (table processing unit) 12 relative to the chuck table 6 in the holding member processing step S20. As illustrated in FIG. 10, when the chuck table 6 and the processing unit 12 to which the polishing pad 54 is mounted are moved relative to each other vertically and horizontally along two line segments that connect the intermediate points of the opposite sides of the holding surface 10a having a rectangular shape, while the polishing pad 54 is in contact with the holding member 10 of the chuck table 6, in a state in which the table processing unit 12 is rotating, an X-shaped region that is a part of the holding member 10 forming the holding surface 10a and that is along the two line segments is ground.

As an example of a more specific step, for example, first, the rotating polishing pad 54 comes into contact with the holding surface 10a of the chuck table 6 that is not rotating. When the chuck table 6 is moved back and forth along the X-axis direction by the X moving mechanism 22 (see FIG. 2) in such a state, the polishing pad 54 moves back and forth relative to the chuck table 6.

The polishing pad 54 moves on the line segment that connects the intermediate points of the opposite sides of the holding surface 10a of the chuck table 6. The movement range of the polishing pad 54 is set within a range between the intermediate point of the line segment (the center of the holding surface 10a) and the one end of the line segment (the intermediate point of one side of the holding surface 10a). As a result, a region along half of one line segment of the two line segments connecting the intermediate points of the opposite sides of the square holding surface 10a is processed.

Next, the chuck table 6 is rotated by 90° about the rotational axis along the Z-axis direction. In this state, the rotating polishing pad 54 similarly moves on the line segment connecting the intermediate points of the opposite sides of the holding surface 10a of the chuck table 6. Accordingly, a region along half of another line segment of the two line segments connecting the intermediate points of the opposite sides of the square holding surface 10a is processed.

If processing is repeated four times along the line segments connecting the intermediate points of the opposite sides of the holding surface 10a in the manner described above, the X-shaped region described above is processed.

Moreover, if a portion that is a part of the holding member 10 forming the holding surface 10a and that is other than the X-shaped region is processed in a shape protruding more toward the outer side, the outer peripheral protruding shape close to the shape illustrated in FIG. 3 is formed on the holding surface 10a of the chuck table 6 (processed chuck table 6′).

Alternatively, processing may be performed in such a way that the processing unit 12 (see FIGS. 1, 2, 4, and 5) as the table processing unit to which the grinding wheel 18 including the grindstones 20 is attached grounds the holding member 10 of the chuck table 6, an outer peripheral protruding shape similar to the shape formed on the face side of the processed wafer 4′ illustrated in FIG. 3 is formed on the holding surface 10a, and thereafter, the X-shaped region (region along the line segments connecting the intermediate points of the opposite sides of the holding surface 10a) is processed as illustrated in FIG. 10.

If grinding processing is performed on the wafer 4 in a state in which the rectangular wafer 4 is held on the holding surface 10a in such an orientation that the position of the corner portion of the wafer 4 is aligned with the portion of the holding surface 10a that is protruding upward relative to the central region, the holding surface 10a having the outer peripheral protruding shape and being included in the processed chuck table 6′, a processed wafer 4′ in which the uneven thickness is reduced at higher accuracy can be obtained.

Note that it has been described above that the same processing unit 12 functions as both the table processing unit and the workpiece processing unit by replacing the processing member of the processing unit 12 included in one processing apparatus 2 with another processing member, but the configuration of the processing apparatus and the processing unit is not limited to the example described above.

For example, one processing apparatus may include a table processing unit to which a polishing pad is mounted as a processing member and a workpiece processing unit to which a grinding wheel including grindstones as a processing member is mounted, as different processing units. In that case, the processing apparatus includes a workpiece processing unit that has a spindle to which the grindstones are mounted and that grinds the workpiece held on the holding surface of the chuck table, as the first processing unit, and also a table processing unit that rotates the grindstones or the polishing pad mounted as a processing member at a rotational diameter smaller than the minimum width of the holding surface, as a second processing unit separate from the first processing unit.

Alternatively, also possible is a form in which a first processing apparatus including a table processing unit and a second processing apparatus including a workpiece processing unit are different apparatuses, the chuck table or the holding member processed in the first processing apparatus is transferred to the second processing apparatus, and grinding processing of the workpiece is performed in the second processing apparatus.

As another alternative, the processing of the chuck table and the grinding processing of the workpiece may be performed by the same or same type of processing member (for example, the grindstones).

Other structural and methodological details according to the embodiment described above are not limited to those described in the embodiment and can appropriately be modified within the scope of object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing method of a chuck table, comprising:
positioning, relative to each other, the chuck table that has a holding surface for holding a workpiece and that is rotatable about a rotational axis transverse to the holding surface and a processing unit that includes a processing member for processing the holding surface of the chuck table, such that at least a part of the processing member overlaps the holding surface; and
processing a holding member forming the holding surface of the chuck table, wherein,
in the processing the holding member,
the holding member is processed such that the holding surface has an outer peripheral protruding shape in which, relative to an extended surface of a surface formed by a central region that is a portion of the holding surface including a center thereof, at least a part of an outer peripheral region that is on an outer side of the central region is protruding in a direction transverse to the extended surface.

2. The processing method of a chuck table according to claim 1, wherein,
in the processing the holding member,
the processing member is rotated along the holding surface such that a rotational diameter in a direction along the holding surface is smaller than a minimum width of the holding surface, while the chuck table is rotated about the rotational axis, and
the chuck table and the processing member are moved relative to each other in the direction along the holding surface, while the processing member is brought into contact with the central region of the holding surface, to thereby process a portion that forms the central region of the holding surface in the holding member.

3. The processing method of a chuck table according to claim 1, wherein,
in the processing the holding member,
the processing member is rotated along the holding surface such that a rotational diameter in a direction along the holding surface is smaller than a minimum width of the holding surface, while the chuck table is rotated about the rotational axis,
the chuck table and the processing member are moved relative to each other in the direction along the holding surface and in a direction transverse to the holding surface, while the processing member is brought into contact with the holding surface, and
at least a part of a portion that forms the outer peripheral region of the holding surface in the holding member is thereby processed such that the holding surface formed by the holding member has the outer peripheral protruding shape.

4. The processing method of a chuck table according to claim 2, wherein,
in the processing the holding member,
the processing member is rotated along the holding surface such that a rotational diameter in a direction along the holding surface is smaller than a minimum width of the holding surface, while the chuck table is rotated about the rotational axis,
the chuck table and the processing member are moved relative to each other in the direction along the holding surface and in a direction transverse to the holding surface, while the processing member is brought into contact with the holding surface, and
at least a part of a portion that forms the outer peripheral region of the holding surface in the holding member is thereby processed such that the holding surface formed by the holding member has the outer peripheral protruding shape.

5. The processing method of a chuck table according to claim 1, wherein,
in the processing the holding member,
the processing member is rotated along the holding surface such that a rotational diameter in a direction along the holding surface is smaller than a minimum width of the holding surface, while the chuck table is rotated about the rotational axis,
the chuck table and the processing member are moved relative to each other in the direction along the holding surface, while the processing member is brought into contact with the holding surface, and at that time, a rotational speed of one of or both the chuck table and the processing member is changed, and
at least a part of a portion that forms the outer peripheral region of the holding surface in the holding member is thereby processed such that the holding surface formed by the holding member has the outer peripheral protruding shape.

6. The processing method of a chuck table according to claim 2, wherein,
in the processing the holding member,
the processing member is rotated along the holding surface such that a rotational diameter in a direction along the holding surface is smaller than a minimum width of the holding surface, while the chuck table is rotated about the rotational axis,
the chuck table and the processing member are moved relative to each other in the direction along the holding surface, while the processing member is brought into contact with the holding surface, and at that time, a rotational speed of one of or both the chuck table and the processing member is changed, and
at least a part of a portion that forms the outer peripheral region of the holding surface in the holding member is thereby processed such that the holding surface formed by the holding member has the outer peripheral protruding shape.

7. A manufacturing method of a processed chuck table for manufacturing a processed chuck table by processing a chuck table, comprising:
positioning, relative to each other, the chuck table that has a holding surface for holding a workpiece and that is rotatable about a rotational axis transverse to the holding surface and a processing unit that includes a processing member for processing the holding surface of the chuck table, such that at least a part of the processing member overlaps the holding surface; and
processing a holding member that forms the holding surface of the chuck table, wherein,
in the processing the holding member,
the holding member is processed such that the holding surface has an outer peripheral protruding shape in which, relative to an extended surface of a surface formed by a central region that is a portion of the holding surface including a center thereof, at least a part of an outer peripheral region that is on an outer side of the central region is protruding in a direction transverse to the extended surface.

8. A processing method of a workpiece, comprising:
positioning, relative to each other, a chuck table that has a holding surface for holding the workpiece and that is rotatable about a rotational axis transverse to the holding surface and a processing unit that includes a processing member for processing the holding surface of the chuck table, such that at least a part of the processing member overlaps the holding surface;
processing a holding member that forms the holding surface of the chuck table;
holding the workpiece on the holding surface formed by the holding member, after the processing the holding member; and
processing the workpiece by moving the chuck table and a grinding wheel to which grindstones are mounted relative to each other along a rotational axis direction while rotating the chuck table about the rotational axis, rotating the grinding wheel, and bringing the rotating grindstones into contact with the workpiece held on the holding surface, after the holding the workpiece on the holding surface, wherein
the workpiece is a plate-shaped, polygonal object, and,
in the processing the holding member,
the holding member is processed such that the holding surface has an outer peripheral protruding shape in which, relative to an extended surface of a surface formed by a central region that is a portion of the holding surface including a center thereof, at least a part of an outer peripheral region that is on an outer side of the central region is protruding in a direction transverse to the extended surface.

9. A manufacturing method of a processed wafer for manufacturing a processed wafer by processing a wafer which is a workpiece, comprising:
positioning, relative to each other, a chuck table that has a holding surface for holding the workpiece and that is rotatable about a rotational axis transverse to the holding surface and a processing unit that includes a processing member for processing the holding surface of the chuck table, such that at least a part of the processing member overlaps the holding surface;
processing a holding member that forms the holding surface of the chuck table;
holding the workpiece on the holding surface formed by the holding member, after the processing the holding member; and
processing the workpiece by moving the chuck table and a grinding wheel to which grindstones are mounted relative to each other along a rotational axis direction while rotating the chuck table about the rotational axis, rotating the grinding wheel, and bringing the rotating grindstones into contact with the workpiece held on the holding surface, after the holding the workpiece on the holding surface, wherein the workpiece is a plate-shaped, polygonal wafer, and,
in the processing the holding member,
the holding member is processed such that the holding surface has an outer peripheral protruding shape in which, relative to an extended surface of a surface formed by a central region that is a portion of the holding surface including a center thereof, at least a part of an outer peripheral region that is on an outer side of the central region is protruding in a direction transverse to the extended surface.

10. A processing apparatus for processing a workpiece, comprising:
a chuck table to which a holding member that forms a holding surface for holding the workpiece is attached and that rotates along a rotational axis transverse to the holding surface;
a table processing unit to which a processing member for processing the chuck table is mounted and that processes the holding member by bringing the processing member into contact with the holding surface of the chuck table;
a moving mechanism that moves the chuck table and the table processing unit relative to each other; and
a controller that controls operations of at least the table processing unit and the moving mechanism, wherein
the controller controls the moving mechanism such that, when the holding member is processed by the table processing unit, the holding surface has an outer peripheral protruding shape in which, relative to an extended surface of a surface formed by a central region which is a portion of the holding surface including a center thereof, at least a part of an outer peripheral region that is on an outer side of the central region is protruding in a direction transverse to the extended surface.

11. The processing apparatus according to claim 10, wherein
the controller
rotates the processing member along the holding surface such that a rotational diameter in a direction along the holding surface is smaller than a minimum width of the holding surface, while rotating the chuck table about the rotational axis,
moves the chuck table and the processing member relative to each other in the direction along the holding surface and in a direction transverse to the holding surface, while bringing the processing member into contact with the holding surface, and
thereby processes at least a part of a portion that forms the outer peripheral region of the holding surface in the holding member, such that the holding surface formed by the holding member has the outer peripheral protruding shape.

12. The processing apparatus according to claim 10, wherein
the controller
rotates the processing member along the holding surface such that a rotational diameter in a direction along the holding surface is smaller than a minimum width of the holding surface, while rotating the chuck table about the rotational axis,
moves the chuck table and the processing member relative to each other in the direction along the holding surface, while bringing the processing member into contact with the holding surface, and at that time, changes a rotational speed of one of or both the chuck table and the processing member, and
thereby processes at least a part of a portion that forms the outer peripheral region of the holding surface in the holding member, such that the holding surface formed by the holding member has the outer peripheral protruding shape.

13. The processing apparatus according to claim 10, further comprising:
a workpiece processing unit that has a spindle to which grindstones are mounted and that processes a workpiece held on the holding surface of the chuck table, wherein
the table processing unit rotates the grindstones or a polishing pad mounted as the processing member by a rotational diameter smaller than a minimum width of the holding surface.

14. The processing apparatus according to claim 11, further comprising:
a workpiece processing unit that has a spindle to which grindstones are mounted and that processes a workpiece held on the holding surface of the chuck table, wherein
the table processing unit rotates the grindstones or a polishing pad mounted as the processing member by a rotational diameter smaller than the minimum width of the holding surface.

15. The processing apparatus according to claim 12, further comprising:
a workpiece processing unit that has a spindle to which grindstones are mounted and that processes a workpiece held on the holding surface of the chuck table, wherein
the table processing unit rotates the grindstones or a polishing pad mounted as the processing member by a rotational diameter smaller than the minimum width of the holding surface.
